(19) United States
(12) Patent Application Publication
(10) Pub. No.: US 2026/0275524 A1
(43) Pub. Date: Sep. 17, 2026

(54) DEFECT DENSITY MANIPULATION OF A DIELECTRIC LAYER IN SEMICONDUCTOR FABRICATION IN AN ATOMIC LAYER DEPOSITION CHAMBER

(71) Applicant: The Research Foundation for the State University of New York, Albany, NY (US)

(72) Inventors: Karsten Beckmann, Albany, NY (US); Nathaniel Cady, Delmar, NY (US); Jubin Hazra, Albany, NY (US)

(21) Appl. No.: 18/536,787

(22) Filed: Dec. 12, 2023

Related U.S. Application Data
(60) Provisional application No. 63/525,045, filed on Jul. 5, 2023.

(51) Int. Cl. C23C 16/458; C23C 16/40; C23C 16/455; H10P 14/60; H10P 14/692; H10P 14/694

(52) U.S. Cl. CPC C23C 16/4584; C23C 16/405; C23C 16/45544; H10P 14/6339; H10P 14/692; H10P 14/694

(57) ABSTRACT

A system, process, and semiconductor device created from depositing a dielectric layer having a predetermined concentration of defects, such as oxygen or nitrogen vacancies, in a spatial atomic layer deposition (ALD) chamber. The ALD has a rotating platform that rotates between the ALD process chambers, and at least one substrate is located on the rotating platform and a dielectric layer film is deposited over the at least one substrate within at least one ALD process chamber whereby rotation of the platform at a predetermined velocity will cause the dielectric layer to include a predetermined concentration of defects. Multiple substrates can be placed on the rotating platform such that batches of semiconductors can be made having dielectric layers with predetermined defect densities.

### CROSS-REFERENCE TO RELATED APPLICATION

This Application claims the benefit of U.S. Provisional Application No. 63/525,045, filed Jul. 5, 2023, the entirety of which is hereby incorporated herein by this reference.

### STATEMENT REGARDING FEDERALLY SPONSORED RESEARCH

This invention was made with government support under grant no. FA8750-19-1-0014 awarded by U.S. Air Force Research Laboratory. The government has certain rights in the invention.

### BACKGROUND OF THE INVENTION

### 1. Field of the Invention

The present invention generally relates to semiconductors and methods of their fabrication. More particularly, the present invention relates to a system and method for fabricating thin films in an atomic layer deposition (ALD) tool.

### 2. Description of the Related Art

Resistive random-access memory (ReRAM or RRAM) is a type of non-volatile computer memory that works by changing the resistance across a dielectric solid-state material, sometimes called a memristor or resistive memory. The fabrication of ReRAM involves generating oxygen vacancy defects in a thin oxide layer (oxygen locations where the oxygen has been removed). These vacancies become mobile under high fields and current and their move changes the conductivity of the film.

ReRAM technology is becoming popular because of high storage density, high speed to read and write, low power consumption, a simple configuration, compatibility with CMOS, and potential for scaling down to the nanometer scale. The switching layer usually has an asymmetric structure where an insulating layer (HfO₂, TiO₂, ZrO₂, Ta₂O₅, etc.) is sandwiched between an oxygen exchange layer (Hf, Ti) and an inert electrode (Pt, Ir, TiN, TaN). Generally, the ReRAM device can be switching in from a high to a low resistance state by applying a applying an electric potential at its electrodes. The technology is not limited a specific physical principle but rather specified by its response to this potential difference. Henceforth, a brought set of materials can be used to achieve various physical effects that result in the described resistance change.

Atomic layer deposition (ALD) is a thin-film deposition technique based on the sequential use of a gas-phase chemical process. ALD is considered a subclass of chemical vapor deposition (CVD). ALD reactions use two chemicals called precursor and co-reactant that interact with the current surface of a substrate material one at a time in a sequential manner. A thin film is slowly deposited on the substrate through repeated exposure to separate precursors. The ALD process in widely used in fabricating semiconductor devices and synthesizing nanomaterials.

In conventional atomic layer deposition (ALD), the substrate is exposed to the precursors and co-reactant sequentially and the gases are separated via a purge pulse with an inert gas (i.e. N₂, Ar, He). Spatial ALD is a variation of ALD in which precursors are continuously supplied in different locations and kept apart by an inert gas region or zone. Film growth is achieved by exposing the substrate to the locations containing the precursor and co-reactant. One type of a spatial ALD utilizes a rotating platform between separate chambers, an example of which is the NT333 manufactured by Tokyo Electron Ltd.

During the development of thin films, there are numerous distinct formation phases that impact the eventual film microstructure and its physical characteristics. All thin films begin with a random nucleation process, followed by nucleation and growth stages. Different deposition circumstances, such as growth temperature, growth rate, and substrate surface chemistry, influence the nucleation and growth phases. External forces, like electron or ion bombardments, can influence the nucleation stage. Thin films properties are influenced by the deposition condition. The deposition state of the nucleation stage determines the microstructure, related defect structure, and film stress. Also, the deposition parameters determine the crystal phase and orientation of thin films. The thin film property is influenced by the structure, although the reaction condition and deposition process impact the mechanical and thermal properties of the film. The particles are supplied to the reaction surface one by one to stimulate film growth and the starting state (incidence angle, velocity, and location) of the incident particle is provided as the initial condition.

Defects, such as oxygen vacancies, play a crucial role for resistance switching in ReRAM device. The resistance switching is strongly coupled to the presence and a preferential distribution of defects involving the formation of conduction filaments. The connection and rupture of conductive filaments cause resistance switching between a low resistance state (ON state) and a high resistance state (OFF state). It is known that an oxygen vacancy filament induces several defect states within the band gap of both TiO₂ and NiO, leading to the defect-assisted electron transport. A conductive filament is formed by the migration of oxygen vacancies and the degree of difficulty in the formation of oxygen vacancies and migration process determine the macroscopic properties of devices such as the forming voltage and the SET voltage.

Therefore, it is important to address the physical details of conductive filaments developed through oxygen vacancies in fabricating a film. Moreover, as the defect sites in ReRAM fabrication are typically oxygen vacancies, their concentration is the predominant factor determining the ReRAM switching parameters. It is to this problem that the present invention is primarily directed.

### BRIEF SUMMARY OF THE INVENTION

Briefly described, the present invention is a system, method, and/or semiconductor device produced by depositing a dielectric layer via atomic layer deposition (ALD), where the dielectric layer has a predetermined concentration of defects, such as oxygen or nitrogen defects and is thus sub-stoichiometric. It is a special ALD system with a chuck rotating through sections of a single chamber with varying atmospheres, such as an NT333 from Tokio Electron Ltd.. The substrate is located on the chuck and is typically a silicon wafer (here 300 mm wafer). A dielectric layer is deposited on the substrate by rotating through the various atmospheres and the defect concentration is determined by the angular velocity of the chuck.

The defect concentration of the deposited film of the dielectric layer can be controlled via angular velocity of the rotating platform. An increase in angular velocity results in a more defective film as the time each wafer spends in each chamber section will be reduced. This directly impacts the reaction times within the sections. Whereas at least two section contain a precursor and a co-reactant, respectively, which are typically separated by non-reacting sections. Intentional manipulation of defects can also occur with a decrease in angular velocity, which will result in an increased reaction time within each section thus reducing the defect concentration of the film. Using the present invention, a batch of semiconductor devices, such as ReRAM or capacitors, can be produced with a plurality of substrates on the rotating platform that rotates between one or more process chambers, with the platform rotated at a predetermined velocity such that the dielectric layer includes a predetermined concentration of vacancy defects in the plurality of substrates.

Furthermore, the system can create a dielectric layer that includes a predetermined concentration of oxygen vacancy defects. In such embodiment, the dielectric layer is an oxide layer. Alternately, the dielectric layer can include a predetermined concentration of nitrogen vacancy defects, with the dielectric layer being a nitride layer.

Therefore, the present invention has industrial applicability in that it can intentionally alter the concentration of defects, such as oxygen or nitrogen vacancies, in a functional layer to affect materials properties such as diffusivity, electrical conductivity or both. This invention is particularly advantageous in the controlling the oxygen vacancy defects in ReRAM switching and diffusion layers, which is the predominant factor determining the ReRAM's switching parameters. These and other advantages of the present invention over the prior art will be apparent to one of skill in the art in further view of the drawings and detailed description of this application.

### BRIEF DESCRIPTION OF THE DRAWINGS

FIG. 1 is a top perspective view of the rotating platform of a multi-section spatial atomic layer deposition system producing thin and ultra-thin solid-state films.

FIG. 2 is a cross-section of one embodiment of a ReRAM device having a HfO₂ switching layer with a predetermined concentration of oxygen vacancy defects.

FIG. 3 is a diagram illustrating the effect of angular velocity on the forming voltages for ReRAM devices made with the defect-controlled dielectric layer of the wafer.

FIG. 4A is a diagram illustrating the forming voltage in relation to the rotational speed of the rotating platform and thickness of the dielectric layer for ReRAM devices made with the defect-controlled dielectric layer.

FIG. 4B is a diagram illustrating a graphing plot of the average forming voltage of the layers referenced in FIG. 4A.

FIG. 5A is a diagram illustrating the forming voltage in relation to the rotational speed of the rotating platform and thickness of the layer, specifically illustrating film (layer) thickness increasing the forming voltage for ReRAM devices made with the defect-controlled dielectric layer.

FIG. 5B is a diagram illustrating the switching RESET voltage in relation to the rotational speed of the rotating platform and thickness of the dielectric layer for ReRAM devices made with the defect-controlled dielectric layer.

FIG. 5C is a diagram illustrating the switching SET voltage in relation to the rotational speed of the rotating platform and thickness of the layer for ReRAM devices made with the defect-controlled dielectric layer.

FIG. 6A is a diagram illustrating the switching operating parameters for ReRAM devices made with the defect-controlled dielectric layer, with the average high reset resistance (HRS).

FIG. 6B is a diagram illustrating the switching operating parameters for ReRAM devices made with the defect-controlled dielectric layer, with the average low reset resistance (LRS).

FIG. 7 is a diagram illustrating the switching operating parameters and Set/Reset voltages for ReRAM devices made with the defect-controlled dielectric layer.

FIG. 8A is a diagram illustrating a Pulse I-V curve for a yielded ReRAM device with a defect-controlled dielectric layer.

FIG. 8B is a diagram illustrating a Pulse I-V curve for an un-yielded ReRAM device with a defect-controlled dielectric layer.

FIG. 9A is a diagram illustrating the area dependence of capacitance of a defect-controlled dielectric layer used to manufacture a metal-insulator-metal (MIM) capacitor, shown here in logarithmic representation in relation to rotational speed of the rotating platform.

FIG. 9B is a diagram illustrating the area dependence of capacitance of a defect-controlled dielectric layer of the MIM device of FIG. 9A, shown here in linear representation in relation to rotational speed of the rotating platform.

FIG. 9C is a diagram illustrating the dielectric constant versus area of a defect-controlled dielectric layer of an MIM device, shown here in in relation to rotational speed of the rotating platform.

FIG. 10 is a diagram illustrating a diagram illustrating the dielectric constant versus area of a defect-controlled dielectric layer used to construct a MIM capacitor, shown here in in relation to rotational speed of the rotating platform.

FIG. 11 is a graph illustrating the capacitance-frequency trade-off caused by increasing the dielectric constant in the dielectric layer by controlling the defects present in the layer.

FIG. 12 is a diagram illustrating normalized capacitance versus bias voltage of an MIM capacitor having a defect-controlled layer of FIGS. 9A-11.

FIG. 13 is a diagram illustrating voltage coefficients versus rotational speed of a rotating platform creating an MIM capacitor having a defect-controlled layer of FIGS. 9A-12.

FIG. 14 is a diagram illustrating capacitance voltage of an MIM capacitor having a defect-controlled layer created at high rpm of the rotating platform.

FIG. 15 is a diagram illustrating capacitance versus frequency of an MIM capacitor having a defect-controlled layer like those of FIGS. 9A-13.

FIG. 16 is a diagram illustrating capacitance versus frequency of an MIM capacitor having a defect-controlled layer of FIGS. 9A-13, with the effects of various rotational speeds of the rotating platform illustrated.

FIG. 17 is a diagram illustrating voltage capacitance of an MIM capacitor having a defect-controlled layer of FIGS. 9A-13, with the effects of various rotational speeds of the rotating platform illustrated.

FIG. 18 is a diagram illustrating a “In(J) versus sqrt(E)” plot of an MIM capacitor having a defect-controlled layer of FIGS. 9A-13.

FIG. 19 is a diagram illustrating voltage capacitance of an MIM capacitor having a defect-controlled layer of FIGS. 9A-13, with the effects of various rotational speeds and repetitions thereof of the rotating platform illustrated.

FIG. 20 is a diagram illustrating dielectric constant versus area of an MIM capacitor having a defect-controlled layer of FIGS. 9A-13, with the effects of various rotational speeds and repetition of speeds of the rotating platform of FIG. 19 illustrated.

### DETAILED DESCRIPTION OF THE INVENTION

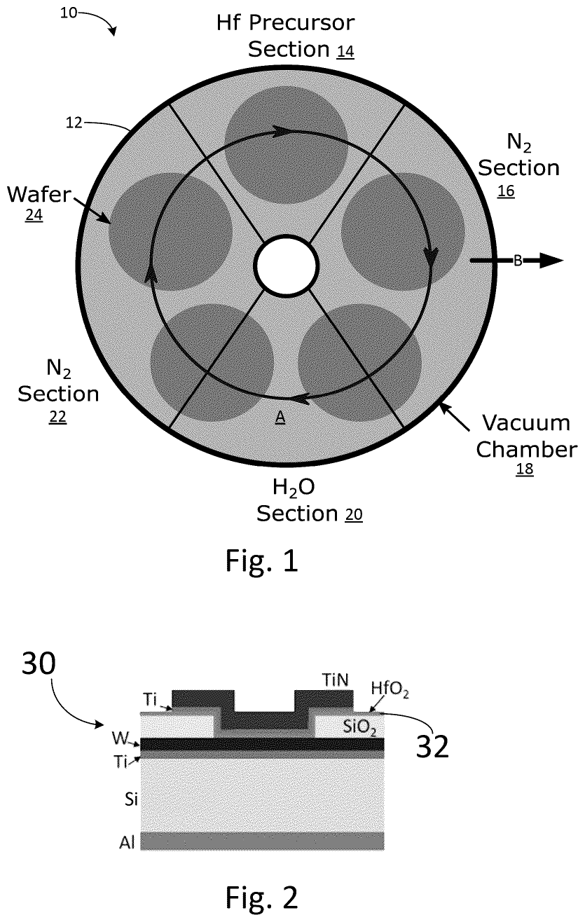

With reference to the figures in which like numerals represent like elements throughout the several views, FIG. 1 is a top perspective view of the rotating platform 12 of a multi-chamber spatial atomic layer deposition system 10 producing batches of thin films on 5 wafers (typically silicon wafers but not limited to silicon). In this embodiment, the system 10 the rotating platform 12 rotates between one or more ALD reactants, here being a Hf precursor section 14, a first N₂ section 16, and H₂O section 20, and a second N₂ section 22. The stages are performed under a partial vacuum with a plasma in section 14 and 20chamber 18.

In general, an ALD process consists of sequential alternating pulses of gaseous chemical precursors that react with the substrate (Wafer 24). These individual gas-surface reactions are typically called ‘half-reactions’ and appropriately make up only part of the full materials synthesis. During each half-reaction, a precursor is pulsed into a chamber under vacuum (<1 Torr) (Vacuum chamber 18) for a designated amount of time to allow the precursor to fully react with the substrate (Wafer 24) surface through a self-limiting process that leaves no more than one monolayer at the surface. Subsequently, the chamber is purged with an inert carrier gas (typically N2 or Ar), here first N2 section and second N2 section 22, to remove any unreacted precursor or reaction by-products. This is then followed by the counter-reactant precursor pulse and purge, creating up to one layer of the desired material. This process is then cycled until the appropriate film thickness is achieved. Typically, ALD processes are conducted at modest temperatures (<350° C.).

In the present embodiment, the NT333 semi-batch atomic layer deposition (ALD) chamber can be utilized, the rotating platform 12 of which is shown in FIG. 2. Here, the NT333 and is capable of depositing various films on up to five 300 mm wafers simultaneously. The vacuum chamber 18 is separated into four distinct sections enabling the deposition via the rotation of the five wafers through the individual sections, shown by rotational arrow A.

The ultimate defect concentration of the deposited film of the dielectric layer, embodied here as a HfO2 switching layer, can be controlled via as angular velocity (shown at arrow B) from the rotational speed of the rotating platform 12. An increase in angular velocity B results in a more defective film as the time each wafer spends in each chamber section will be reduced. This directly impacts the reaction times of the metal precursor (such as done at Hf precursor section 14) and water application (such as done at H20 section 20), respectively. Intentional manipulation of defects can also occur with a decrease in angular velocity B, which will result in an increased reaction time thus reducing the defect concentration of the film. Using the present invention, a batch of semiconductor devices, such as ReRAM (30 in FIG. 2), can be produced with a plurality of substrates (Wafer 24) on the rotating platform 12.

FIG. 2 shows a cross-section of one embodiment of a ReRAM device 30 having a HfO2 layer 32 with a predetermined concentration of oxygen vacancy defects produced by the system 10 in FIG. 1. Here, the dielectric layer of HfO2 can be between 1-100 nm in thickness and is preferably between 2-20 nm. The dielectric is preferably produced in a sub-stochiometric state such that a predetermined number of defects, such as oxygen or nitrogen vacancies can be maintained. This permits the manipulation of the semiconductor switching parameters.

In prior art fabrication processes, it was difficult to manufacture films (as layers) below the O2 saturation limit such that a desirable number of defects are present at the interface of the dielectric layer, where switching is the most affected. Through the present invention, a desirable level of predetermined defects can be set for the dielectric layer to produce a consistent switching parameter. Thus, the present invention can be used to create semiconductor devices, such as ReRAM, photonics devices, and in films where it is desired to control levels of either vacancy-resistive switching or in ion-control migrations, such as batteries or other ion-flow devices.

In one embodiment, the dielectric layer (such as HfO2 layer 32) can be an oxide layer comprised of at least one material selected from the group consisting of: silicon dioxide, praseodymium oxide, erbium oxide, hafnium oxide, tantalum oxide, aluminum oxide, lanthanum oxide, yttrium oxide, dysprosium oxide, ytterbium oxide, zirconium oxide, titanium oxide, nickel oxide, and zinc oxide. In such embodiment, the rotating platform 12 (FIG. 1) is rotated at a predetermined velocity such that the dielectric layer includes a predetermined concentration of oxygen vacancy defects. In an alternate embodiment, the dielectric layer (such as Hfo2 layer 32) can be a nitride layer comprised of at least one material selected from the group consisting of: carbon nitride, silicon nitride, gallium nitride, boron nitride, tantalum nitride, titanium nitride, and aluminum nitride.

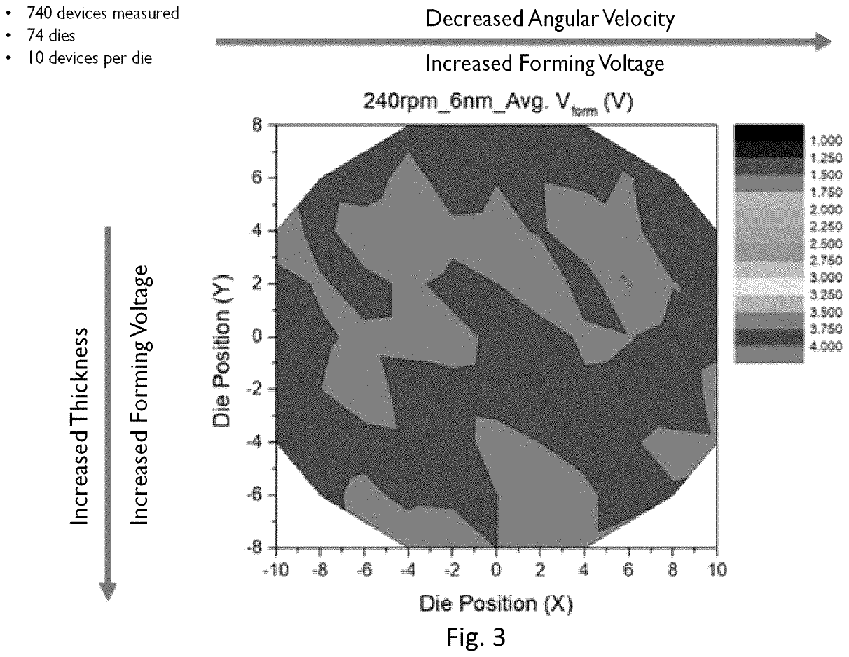

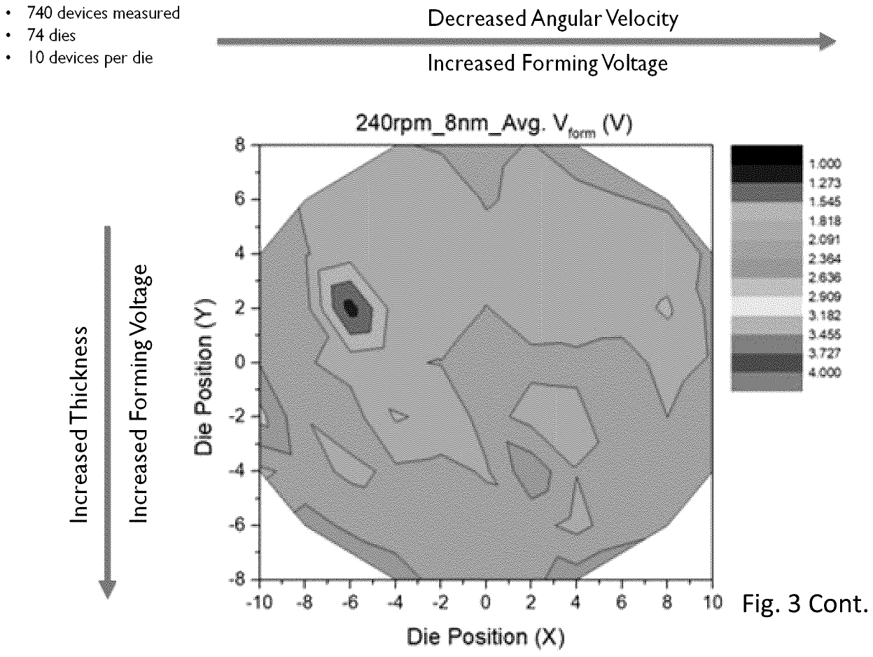

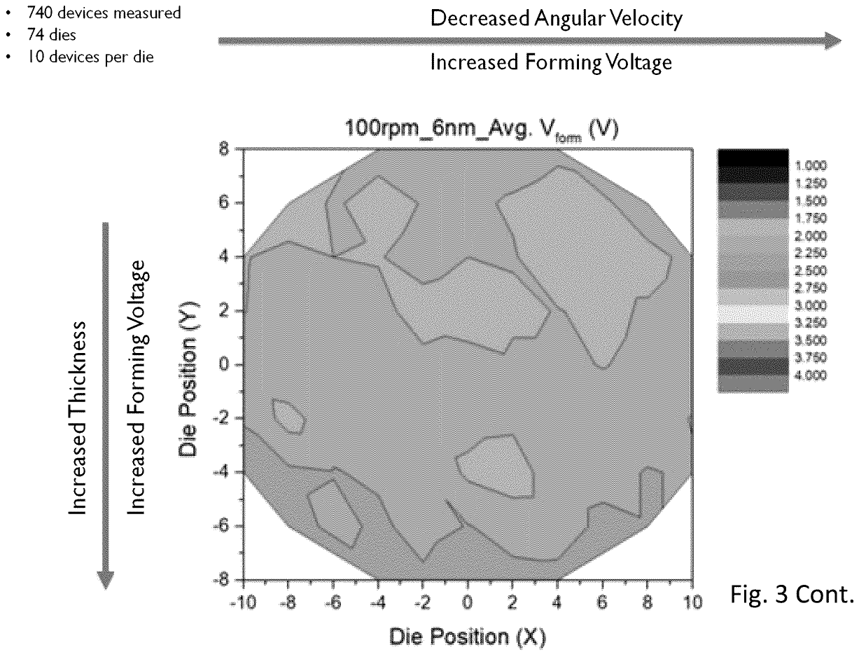

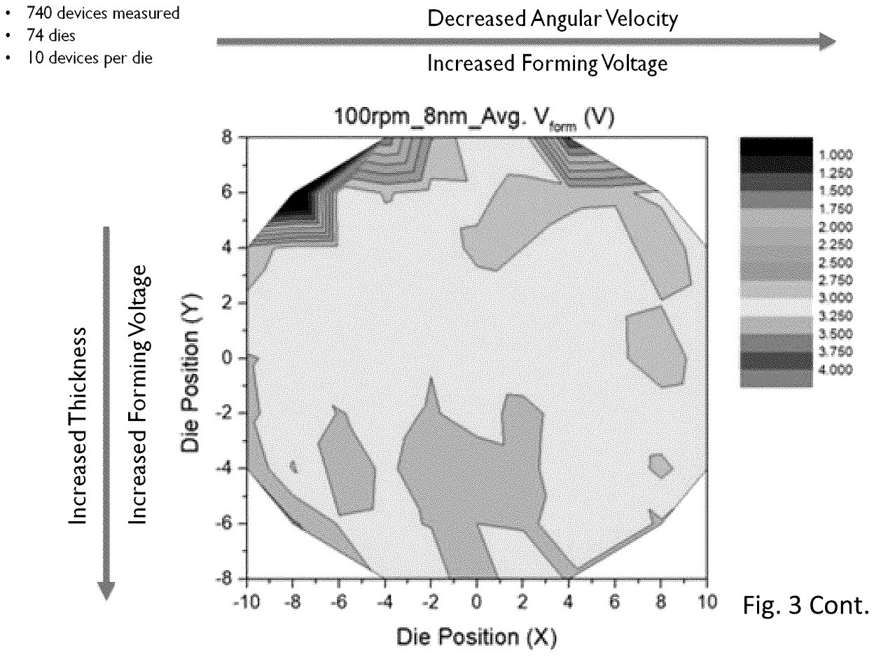

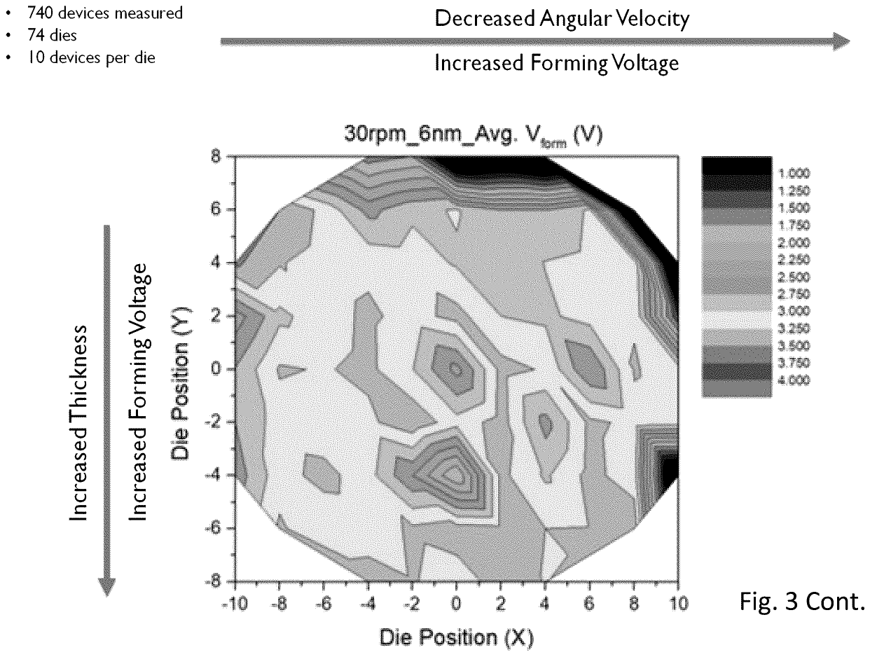

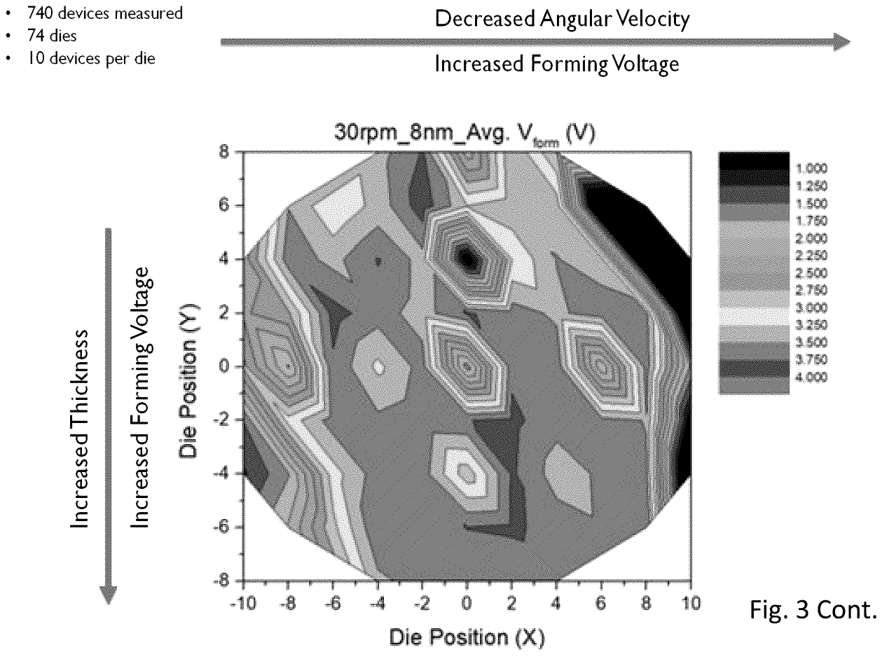

FIG. 3 is a diagram 36 illustrating the effect of angular velocity of the rotating platform 12 (FIG. 1) on the forming voltages in the dielectric layer of the wafer 24 for ReRAM devices (such as ReRAM device 30 in FIG. 2) made with the defect-controlled dielectric layer. As is shown, the lesser the angular velocity (arrow B in FIG. 1), the increased thickness of the layer (such as HfO2 layer 32 in FIG. 2) and the increased forming voltage across the layer, i.e. the greater the switching voltage is needed to utilize the states of the device. Consequently, FIG. 3 demonstrates that controlling the angular velocity of the rotating platform 12 (FIG. 1) allows the control of the thickness of the dielectric layer and thus the level of defects present.

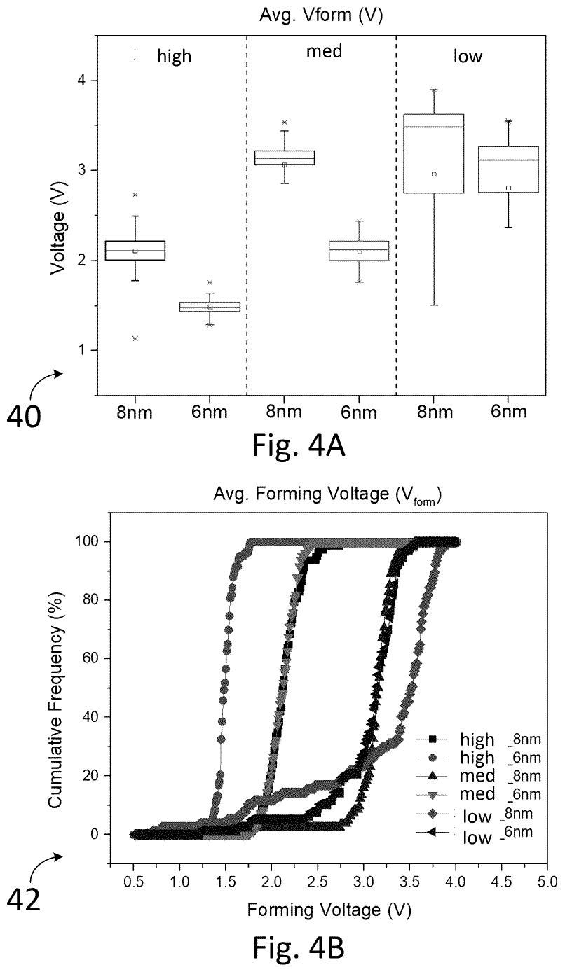

FIG. 4A is a diagram 40 illustrating the forming voltage in relation to the rotational speed of the rotating platform 12 (FIG. 1) and thickness of the layer (such as HfO2 layer 32 in FIG. 2). FIG. 4B is a diagram 42 illustrating a graphing plot of the average forming voltage of the layers referenced in FIG. 4A. FIGS. 4A and 4B demonstrate the specific control that the rotational speed of the rotating platform 12 has over the forming voltages that would be present in the devices utilizing the dielectric layer as a switching layer.

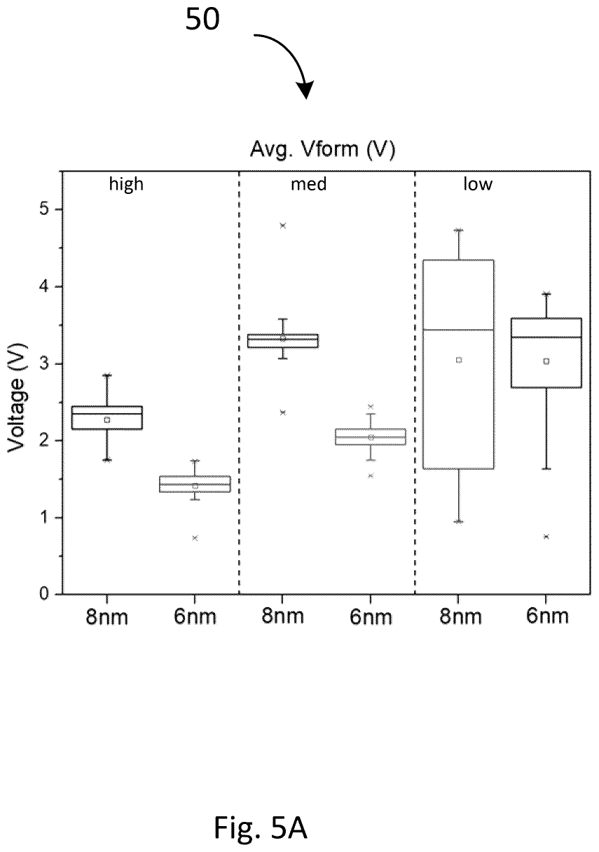

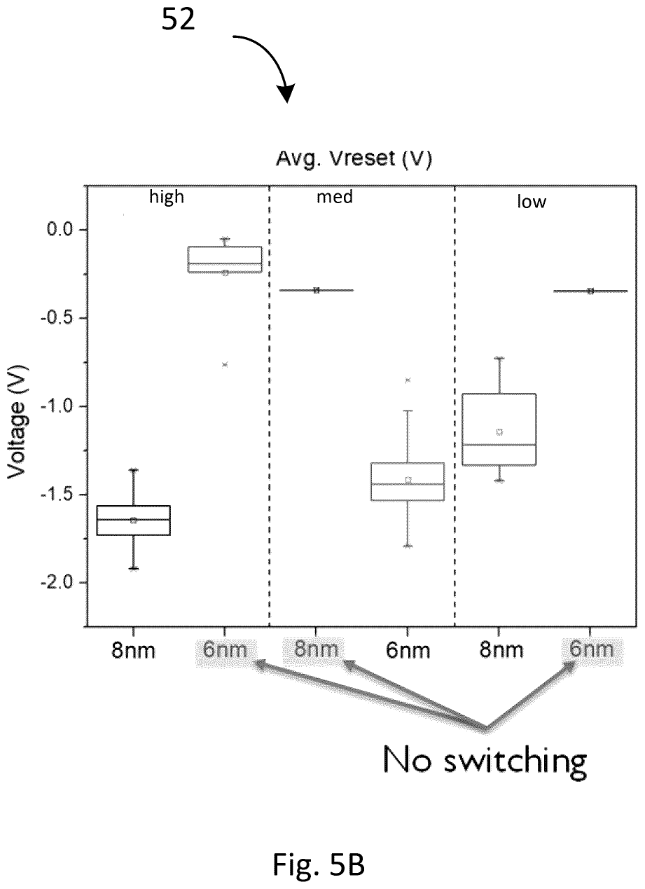

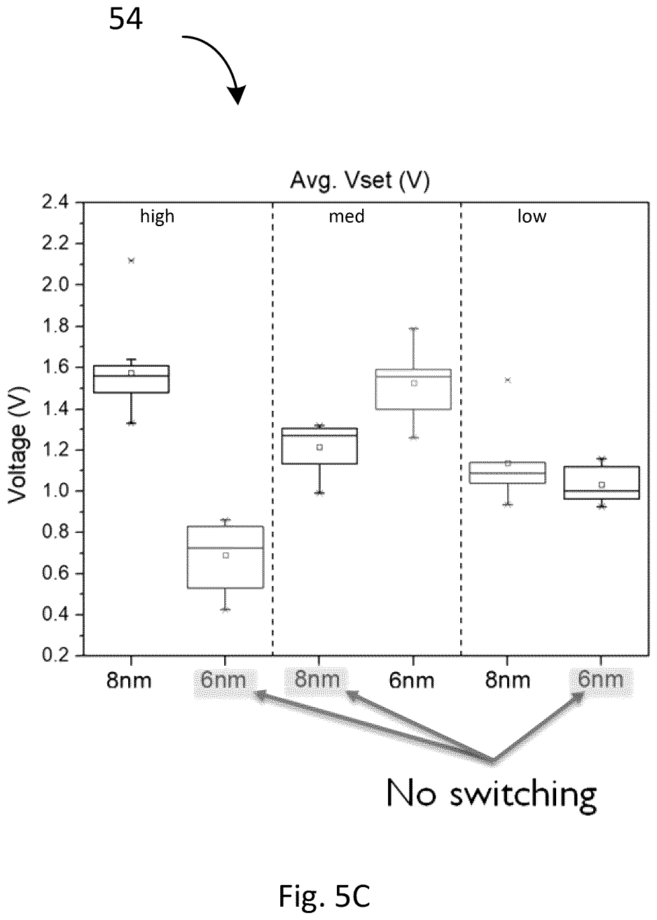

FIG. 5A is a diagram 50 illustrating the forming voltage in relation to the rotational speed of the rotating platform 12 (FIG. 1) and thickness of the dielectric layer (such as HfO2 layer 32 in FIG. 2), specifically illustrating film (layer) thickness increasing the forming voltage. Thus, decreasing the angular velocity (arrow B in FIG. 1) increases the thickness of the layer and forming voltage, as is also illustrating in FIG. 3. FIG. 5B is a diagram 52 illustrating the switching RESET voltage in the dielectric layer in relation to the rotational speed of the rotating platform 12 and thickness of the layer. FIG. 5B likewise shows the rotational speed and thickness at which no switching occurs. FIG. 5C is, similarly to FIG. 5B, a diagram 54 illustrating the switching SET voltage in the dielectric layer in relation to the rotational speed of the rotating platform 12 and thickness of the dielectric layer. FIG. 5C likewise shows the rotational speed and thickness at which no switching occurs.

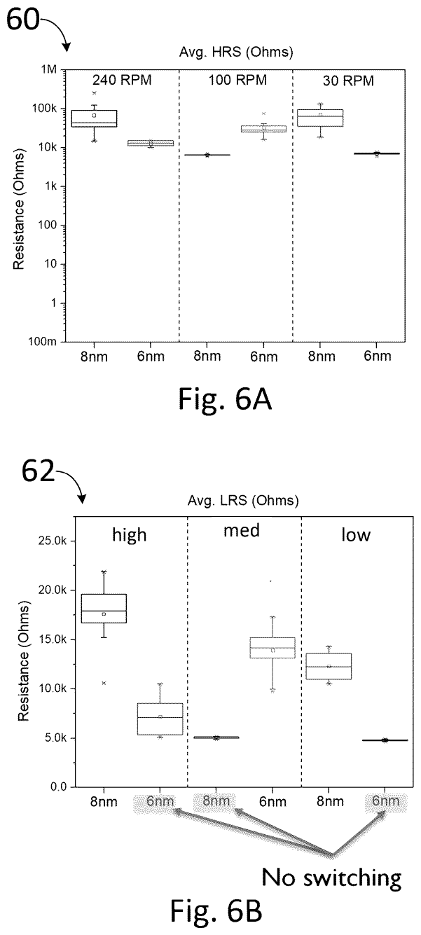

FIG. 6A is a diagram 60 illustrating the switching operating parameters for ReRAM devices (ReRAM 30 in FIG. 2) made with the defect-controlled dielectric layer (such as HfO2 layer 32 in FIG. 2), with the average high reset resistance (HRS). Here, the Set/Reset voltages amplitude was 2.5V/−2.5V, set/reset pulse width was 10 μs. FIG. 6A demonstrates that higher angular velocity (arrow B in FIG. 1) will cause higher variability in working devices, such as ReRAM 30. FIG. 6B is a diagram 62 illustrating the switching operating parameters for ReRAM devices like those in FIG. 6A made with the defect-controlled dielectric layer, with the average low reset resistance (LRS). FIG. 6B also demonstrates that shorting can be seen in non-switching devices (5 kOhm series resistance).

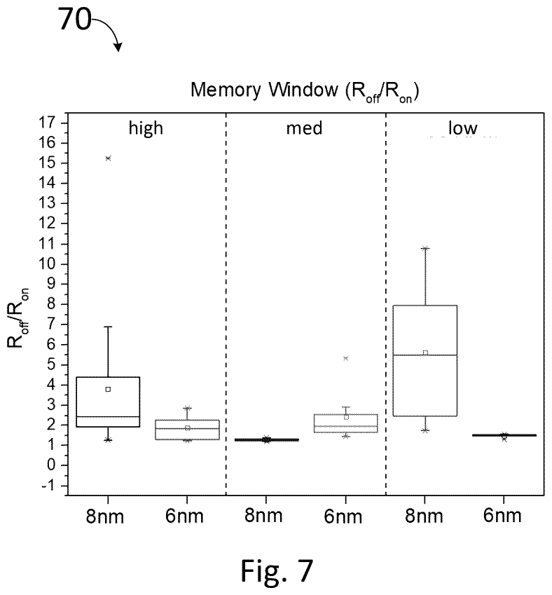

FIG. 7 is a diagram 70 illustrating the switching operating parameters and Set/Reset voltages for ReRAM devices made with the defect-controlled dielectric layer (such as HfO2 layer 32 in FIG. 2). The switching yield for the wafers is:

| Wafer Type | Switching Yield |
|---|---|
| high RPM_8 nm | 100% |
| high RPM_6 nm | 28% |
| Medium RPM_8 nm | 32% |
| medium RPM_6 nm | 88% |
| low RPM_8 nm | 40% |
| low RPM_6 nm | 20% |

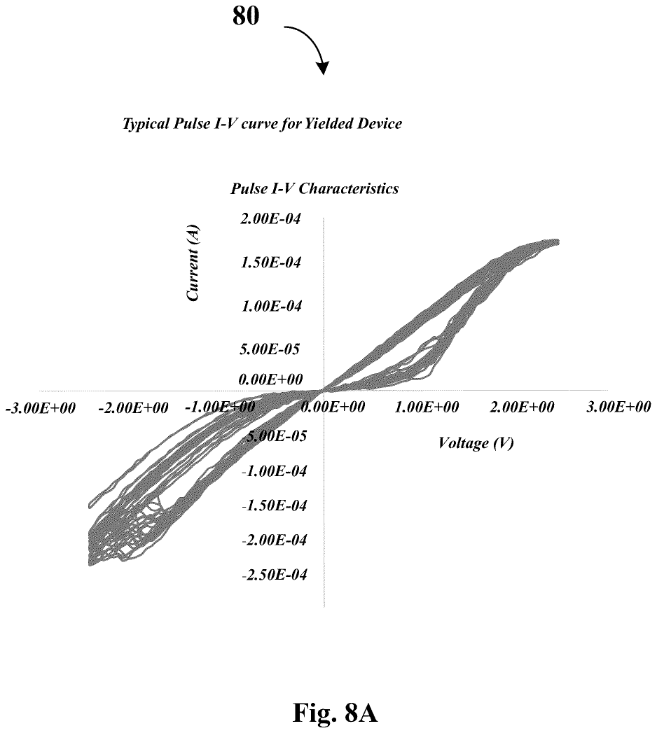

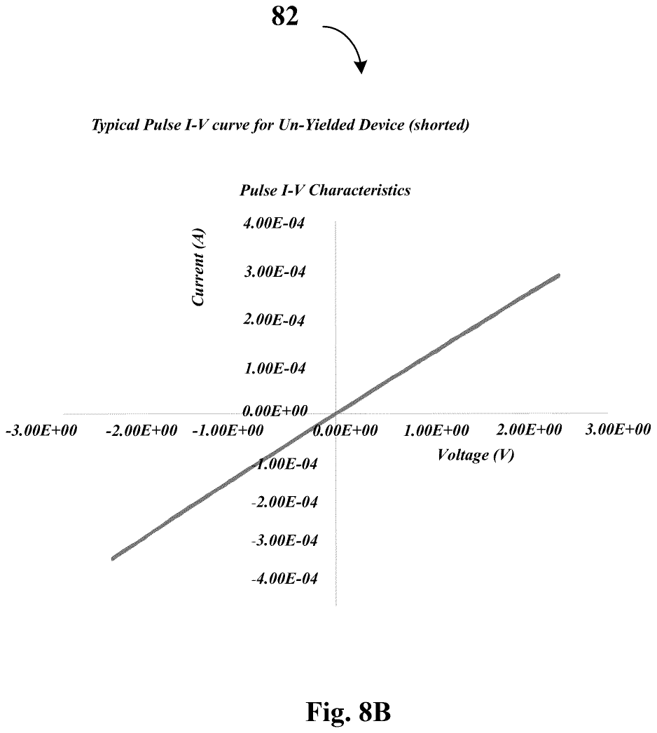

FIG. 8A is a diagram 80 illustrating a Pulse I-V curve for a yielded ReRAM device 30 (FIG. 2) with a defect-controlled dielectric layer(such as HfO2 layer 32 in FIG. 2). FIG. 8B is a diagram 82 illustrating a Pulse I-V curve for a unyielded ReRAM device 30 with a defect-controlled dielectric layer (such as HfO2 layer 32 in FIG. 2), demonstrating the shorting.

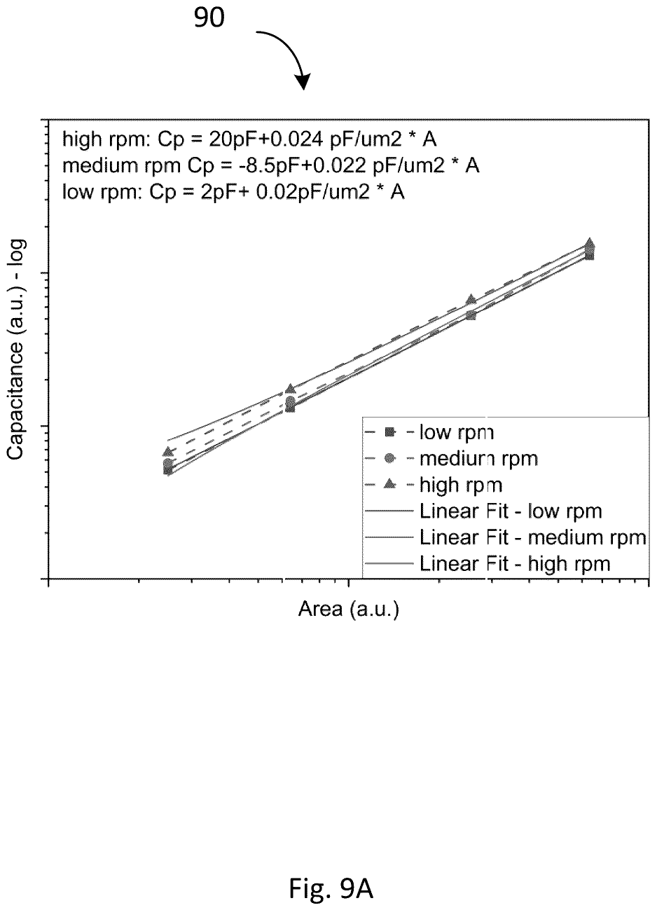

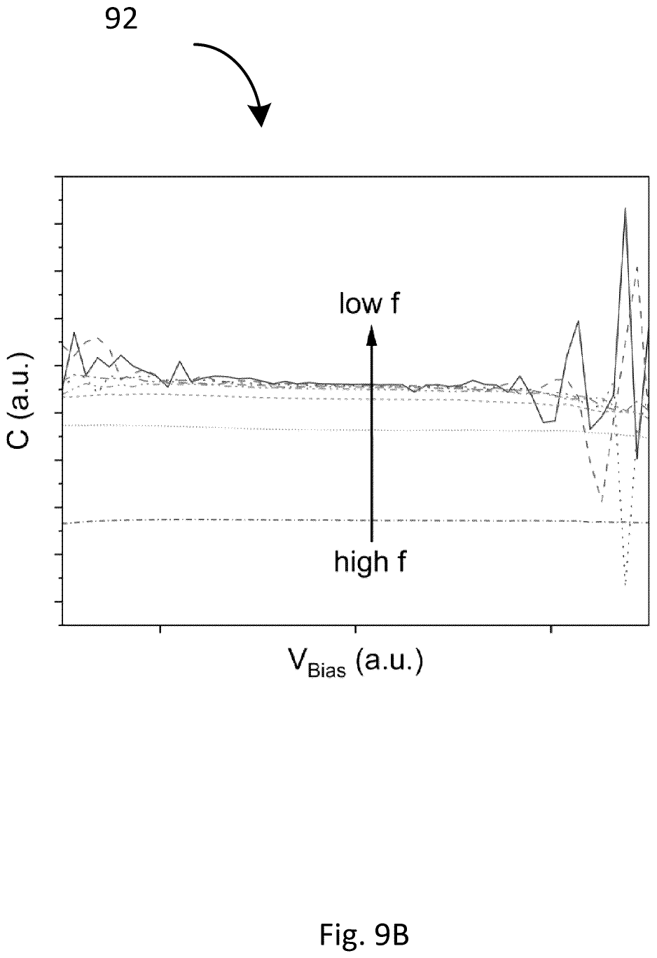

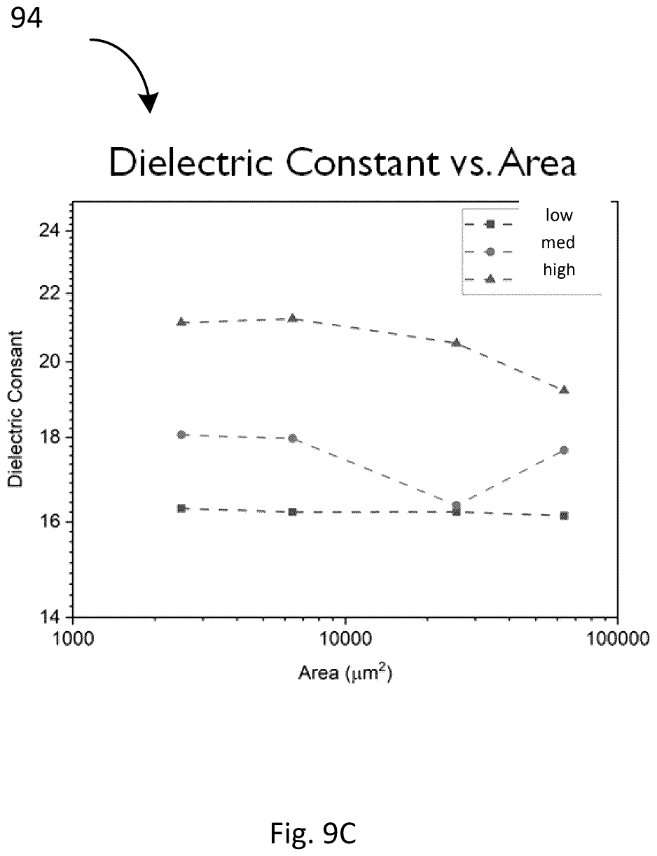

FIG. 9A is a diagram illustrating the area dependence of capacitance of a defect-controlled dielectric layer (such as HfO2 layer 32 in FIG. 2), shown here in logarithmic representation in relation to rotational speed of the rotating platform 12 (FIG. 1). The capacitance scales with Area: −C=ε₀ εr·A/d. It should be noted that higher defect concentration will occur as a result of space-charge polarization. FIG. 9B is a diagram illustrating the area dependence of capacitance of a defect-controlled dielectric layer (such as HfO2 layer 32 in FIG. 2), shown here in linear representation in relation to rotational speed of the rotating platform 12, shown in rpm. FIG. 9C is a diagram illustrating the dielectric constant versus area of a defect-controlled dielectric layer(such as HfO2 layer 32 in FIG. 2, shown here in in relation to rotational speed of the rotating platform 12, shown in rpm.

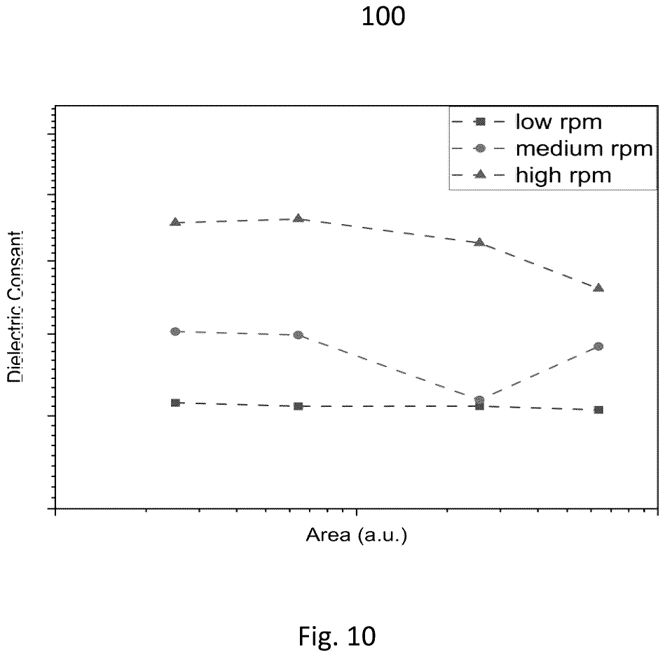

FIG. 10 is a diagram 100 illustrating the dielectric constant versus area of a defect-controlled dielectric layer (such as HfO2 layer 32 in FIG. 2) used to construct a metal-insulator-metal (MIM) capacitor, shown here in in relation to rotational speed of the rotating platform 12. FIG. 10 shows that defects cause mobile electrons contributing to space charge polarization (electronic polarization) increasing the dielectric constant. Thus, higher rotation of the rotating platform 12 results in a higher defect concentration in a dielectric layer of a MIM capacitor.

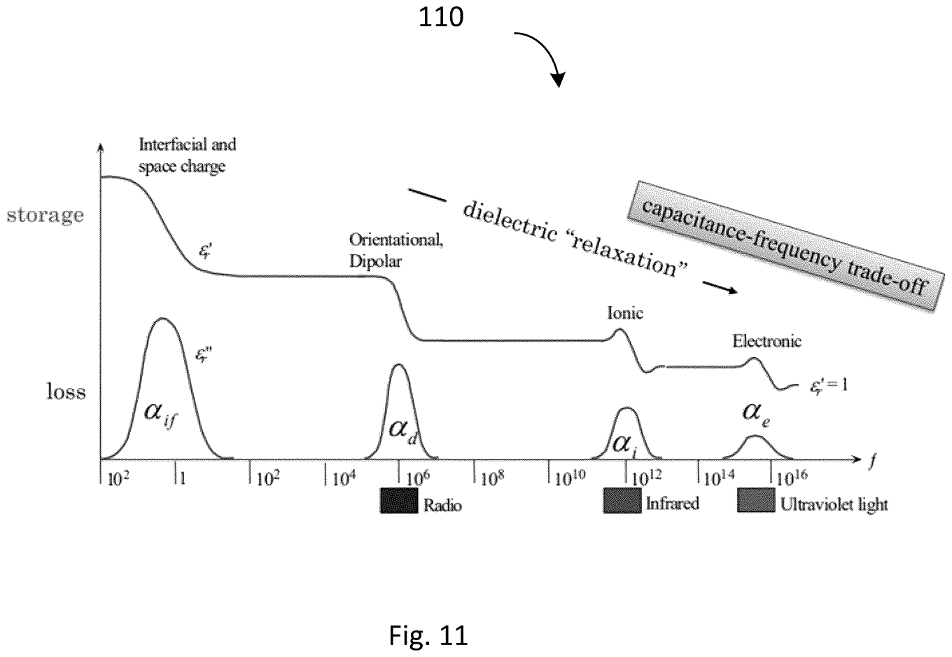

FIG. 11 is a graph 110 illustrating the capacitance-frequency trade-off caused by increasing the dielectric constant in the dielectric layer by controlling the defects present in the layer of the MIM capacitor. The storage and loss of charge in the various electromagnetic bands is shown.

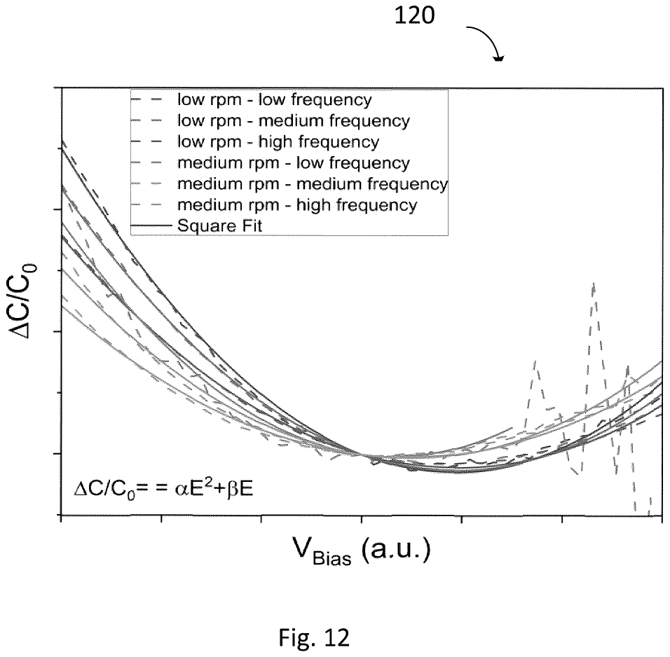

FIG. 12 is a diagram 120 illustrating normalized capacitance versus bias voltage of an MIM capacitor having a defect-controlled layer of FIGS. 9A-11. FIG. 12 shows that capacitance is bias voltage-dependent showing a stronger non-linearity for the low rpm as compared to the medium rpm of the rotating platform 12.

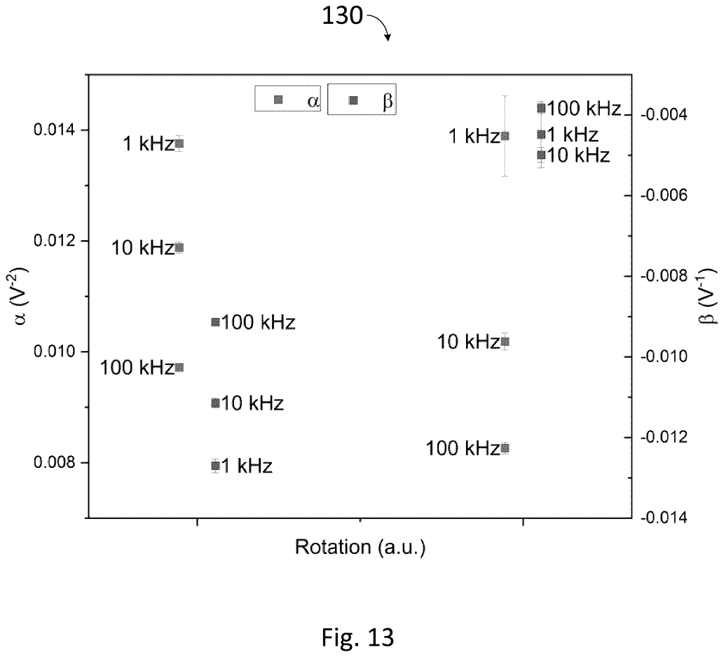

FIG. 13 is a diagram 130 illustrating voltage coefficients versus rotational speed of a rotating platform creating an MIM capacitor having a defect-controlled layer of FIGS. 9A-12. FIG. 13 shows that capacitance is bias voltage-dependent showing a stronger non-linearity for the low rpm as compared to medium rpm of the rotating platform 12.

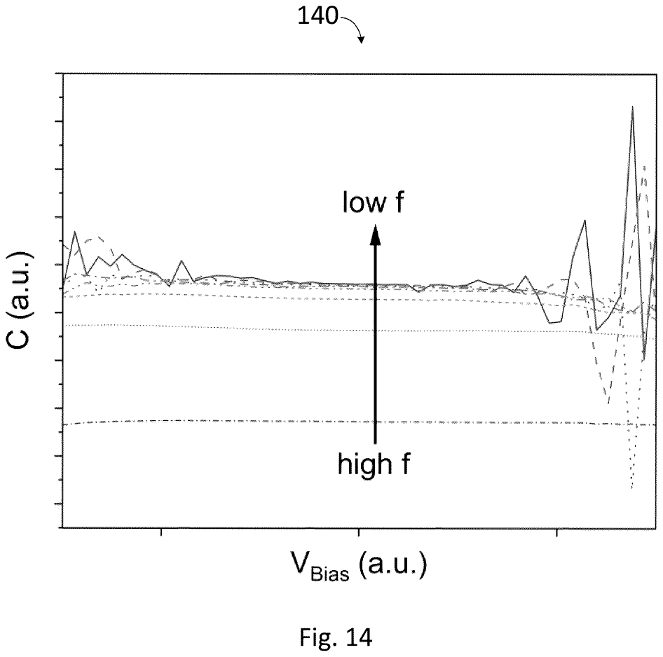

FIG. 14 is a diagram illustrating capacitance voltage of an MIM capacitor having a defect-controlled layer created at high rpm of the rotating platform. FIG. 14 demonstrates that the high rpm of the rotating platform 12 showed a strong voltage dependency due to defect-induced current fluctuations in the dielectric layer.

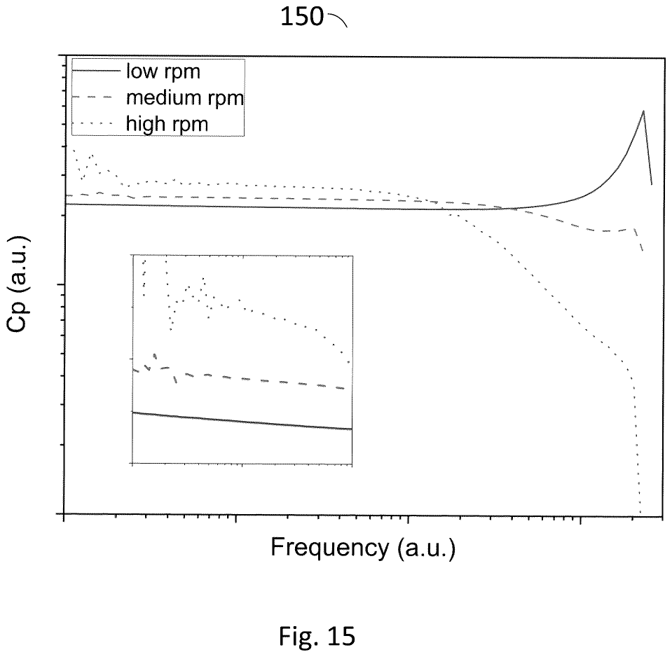

FIG. 15 is a diagram 150 illustrating capacitance versus frequency of an MIM capacitor having a defect-controlled layer like those of FIGS. 9A-13. FIG. 15 demonstrates an increased interface effect with an increase in rpm of the rotating platform 12.

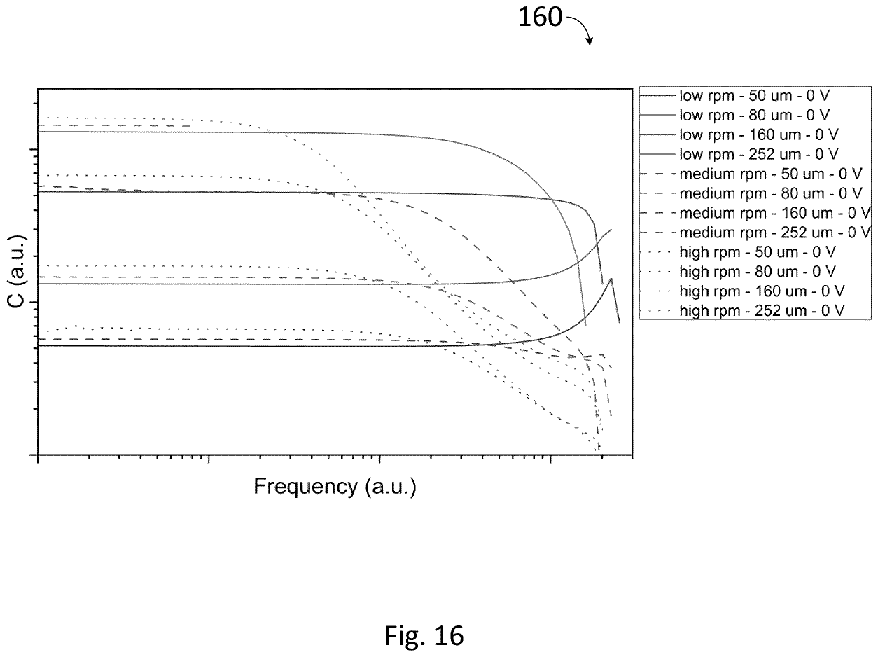

FIG. 16 is a diagram 160 illustrating capacitance versus frequency of an MIM capacitor having a defect-controlled layer of FIGS. 9A-13, with the effects of various rotational speeds of the rotating platform illustrated. FIG. 16 also illustrates a shift of dipole to ionic polarization frequency with higher rotational speed of the rotating platform 12.

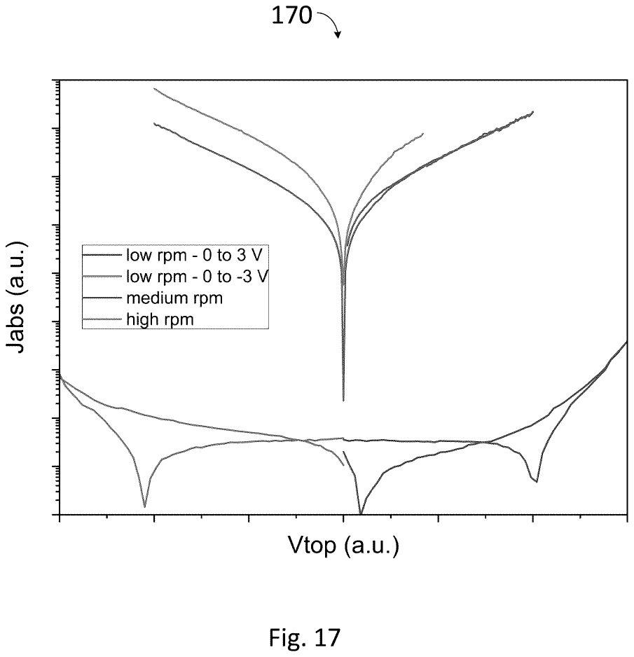

FIG. 17 is a diagram 170 illustrating voltage capacitance of an MIM capacitor having a defect-controlled layer of FIGS. 9A-13, with the effects of various rotational speeds of the rotating platform illustrated. As shown in FIG. 17, generally, current increases with increased rotational speed caused by a higher number of defects. Thus, the HfO2 dielectric layer at I is extremely low and non-capacitive current and can only be detected above 2 to 2.5V not allowing for a current transport determination via the I-V curve.

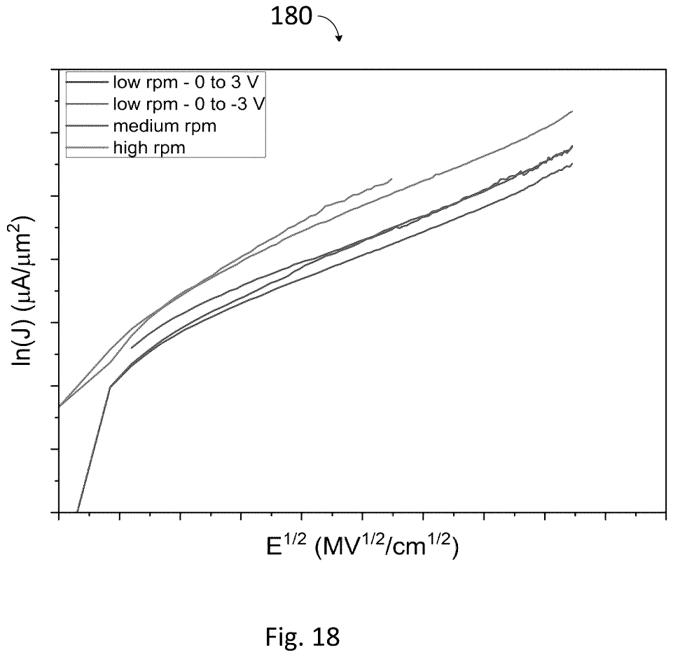

FIG. 18 is a diagram 180 illustrating a “In(J) versus sqrt(E)” plot of an MIM capacitor having a defect-controlled layer of FIGS. 9A-13. FIG. 18 shows that the HfO₂ dielectric layer at medium rpm and high rpm show a Schottky emission based current transport (In(J) vs sqrt(E) plot). This indicates that, based on the rotational speed of the rotating platform 12, the current transport moved to an interface-limited current rather than a bulk-limited current.

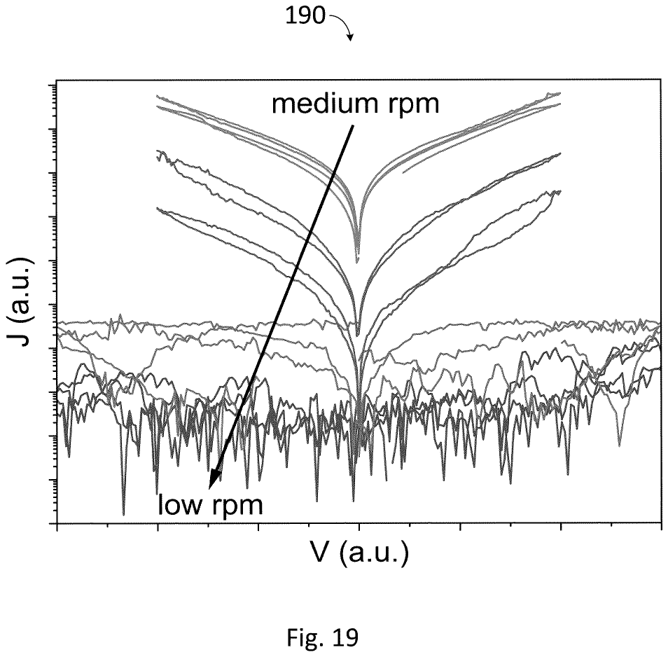

FIG. 19 is a diagram illustrating voltage capacitance of an MIM capacitor having a defect-controlled layer of FIGS. 9A-13, with the effects of various rotational speeds from low to medium rpm with two repetitions thereof of the rotating platform illustrated. FIG. 10 illustrates the effects of repetitive steps of rotational speed of the rotating platform.

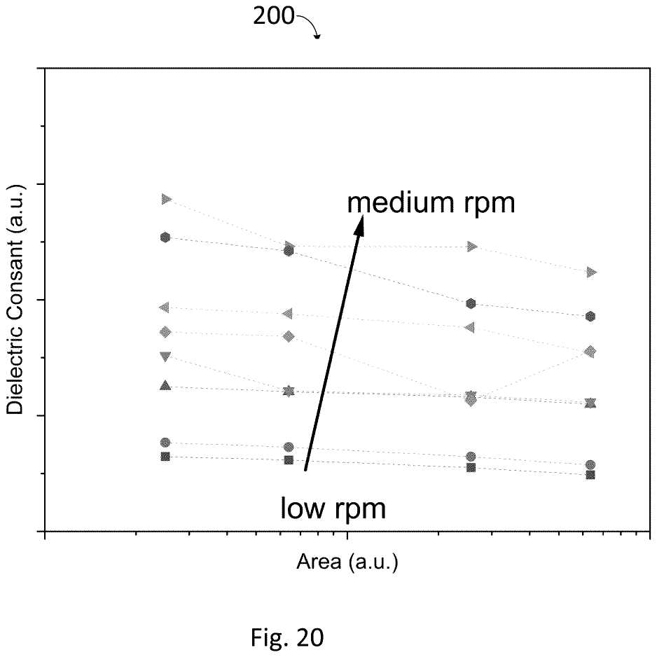

FIG. 20 is a diagram illustrating dielectric constant versus area of an MIM capacitor having a defect-controlled layer of FIGS. 9A-13, with the effects of various rotational speeds and repetition of speeds of the rotating platform 12 of FIG. 19 illustrated. The same speeds as in the table above are utilized. This testing shows that defects cause mobile electrons contributing to space charge polarization (electronic polarization) increases the dielectric constant. Thus, once again demonstrating that higher rpm of the rotating platform 12 results in a higher defect concentration.

From the above description, it can thus be seen that the present invention provides a process for atomic layer deposition (ALD) that includes the steps of providing at least one substrate (such as wafer 24) on a rotating platform 12 that rotates between one or more process chambers, such as Hf precursor section 14, first N2 section 16, H20 section 20 and second N2 section 22. The process then includes the step of depositing a dielectric layer (such as HfO2 layer 32 in FIG. 2) over the at least one substrate (Wafer 24), and then rotating the platform at a predetermined velocity, such as in a range from 10 rpm to 500 rpm, such that the dielectric layer (HfO2 layer 32) includes a predetermined concentration of defects, such as oxygen or nitrogen vacancies.

As shown in FIG. 1, the process can make a batch of semiconductor devices, such as ReRAM, by providing a plurality of substrates (Wafer 24) on a rotating platform 12 that rotates between one or more process chambers. The process can also include depositing at least one layer of a metal oxide precursor (such as in Hf precursor section 14) prior to depositing the dielectric layer, and depositing at least one layer of an H₂O precursor (such as in H₂O section section 20) after the deposition of the dielectric layer, such as shown in FIG. 1.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. An atomic layer deposition (ALD) process, comprising:
providing at least one substrate on a rotating platform that rotates through one or more process sections with different conditions in one chamber;
depositing a thin and ultra-thin film on at least one substrate; and
rotating the platform at a predetermined velocity such that the thin and ultra-thin film experiences different reaction times within each process condition changing the defect concentration within the thin and ultra-thin film.

2. The process of claim 1, further comprising:
providing a plurality of substrates on a rotating platform that rotates between one or more sections within a process chamber; and
rotating the platform at a predetermined velocity such that the thin and ultra-thin film includes a predetermined concentration of defects within the film.

3. The process of claim 1, further comprising creating one or more thin and ultra-thin film layers to build a solid-state or metal-organic device.

4. The process of claim 1, further comprising rotating the platform at a predetermined velocity such that the thin film includes a predetermined concentration of defects within the film.

5. The process of claim 4, wherein depositing a thin film is depositing an oxide layer comprised of at least one material selected from the group consisting of: silicon dioxide, praseodymium oxide, erbium oxide, hafnium oxide, tantalum oxide, aluminum oxide, lanthanum oxide, yttrium oxide, dysprosium oxide, ytterbium oxide, zirconium oxide, titanium oxide, niobium oxide, magnesium oxide, nickel oxide, and zinc oxide among others; and using one precursor and one oxidation process such as H₂O, O₂ or O₃ within two separate process sections.

6. The process of claim 1, further comprising rotating the platform at a predetermined velocity such that the thin and ultra-thin film includes a predetermined concentration of nitrogen vacancy defects.

7. The process of claim 6, wherein depositing a thin and ultra-thin film is depositing a nitride layer comprised of at least one material selected from the group consisting of: carbon nitride, silicon nitride, gallium nitride, boron nitride, tantalum nitride, titanium nitride, and aluminum nitride among others; and using one precursor and one nitridation process such as NH₃ within two separate process sections.

9. A system of depositing a thin or ultra-thin film layer via atomic layer deposition (ALD), comprising:
a rotating platform that rotates between one or more sections within the same process chamber;
at least one substrate located on the rotating platform; and
a thin and ultra-thin film deposited on at least one substrate within at least one ALD process chamber,
wherein the platform being rotated at a predetermined velocity such that the dielectric layer includes a predetermined concentration of defects.

10. The system of claim 9, further comprising:
a plurality of substrates on the rotating platform that rotates between one or more process chambers; and
wherein the platform is rotated at a predetermined velocity such that the thin or ultra-thin film includes a predetermined concentration of defects in the plurality of substrates.

11. The system of claim 9, further comprising one or more thin or ultra-thin films for a solid-state or metal-organic device.

12. The system of claim 9, wherein the platform is rotated at a predetermined velocity such that the thin and ultra-thin film includes a predetermined concentration of cation or oxygen defects.

13. The system of claim 12, wherein the dielectric layer is an oxide layer comprised of at least one material selected from the group consisting of: silicon dioxide, praseodymium oxide, erbium oxide, hafnium oxide, tantalum oxide, aluminum oxide, lanthanum oxide, yttrium oxide, dysprosium oxide, ytterbium oxide, zirconium oxide, titanium oxide, niobium oxide, magnesium oxide, nickel oxide, and zinc oxide among others; and using one precursor and one oxidation process such as H₂O, O₂ or O₃ within two separate process sections.

14. The system of claim 9, wherein the platform is rotated at a predetermined velocity such that the thin or ultra-thin film includes a predetermined concentration of cation or nitrogen defects.

15. The system of claim 14, wherein the dielectric layer film is a nitride layer comprised of at least one material selected from the group consisting of: carbon nitride, silicon nitride, gallium nitride, boron nitride, tantalum nitride, titanium nitride, and aluminum nitride; and using one precursor and one nitridation process such as NH₃ within two separate process sections.

16. A semiconductor device including at least one thin or ultra-thin film having a predetermined concentration of defects, the semiconductor device produced from an atomic layer deposition (ALD) process comprising the steps of:
providing at least one substrate on a rotating platform that rotates between one or more sections in a process chamber;
depositing a dielectric layer over the at least one substrate; and
rotating the platform at a predetermined velocity such that the thin and ultra-thin film includes a predetermined concentration of defects.

17. The film of claim 16, wherein the film is part of one or more ReRAM devices.

18. The film of claim 16, wherein the step of depositing a dielectric layer is depositing an oxide layer including a predetermined concentration of oxygen vacancy defects, and the oxide layer comprised of at least one material selected from the group consisting of: silicon dioxide, praseodymium oxide, erbium oxide, hafnium oxide, tantalum oxide, aluminum oxide, lanthanum oxide, yttrium oxide, dysprosium oxide, ytterbium oxide, zirconium oxide, titanium oxide, niobium oxide, magnesium oxide, nickel oxide, and zinc oxide among others; and using one precursor and one oxidation process such as H₂O, O₂ or O₃ within two separate process sections.

19. The film of claim 16, wherein the step of depositing a dielectric layer is depositing a nitride layer including a predetermined concentration of nitrogen vacancy defects, the nitride layer comprised of at least one material selected from the group consisting of: carbon nitride, silicon nitride, gallium nitride, boron nitride, tantalum nitride, titanium nitride, and aluminum nitride; and using one precursor and one nitridation process such as NH₃ within two separate process sections.

20. The film of claim 16, wherein the step of depositing a dielectric layer deposits the dielectric layer at a thickness of 1-200 nm.

21. A system of depositing a thin or ultra-thin film layer via atomic layer deposition (ALD), comprising:
a rotating platform that rotates between one or more sections within the same process chamber;
at least one substrate located on the rotating platform; and
a thin and ultra-thin film deposited on at least one substrate within at least one ALD process chamber,
wherein the platform being rotated at a predetermined velocity such that the thin or ultra-thin film form a meta-stable film such as NbO₂, NbO, TaO, TaO₂.
